(19) United States
(12) Patent Application Publication
(10) Pub. No.: US 2013/0248353 A1
(43) Pub. Date: Sep. 26, 2013

(54) DEEP-UV OPTICAL COATING PREPARATION METHOD USING SPUTTERING DEPOSITION WITH PURE METAL TARGET

(71) Applicants: Cheng-Chung Lee, Pin-Cheng (TW); Bo-Huei Liao, Sinshe Township (TW)

(72) Inventors: Cheng-Chung Lee, Pin-Cheng (TW); Bo-Huei Liao, Sinshe Township (TW)

(73) Assignee: NATIONAL CENTRAL UNIVERSITY, Jhongli City (TW)

(21) Appl. No.: 13/426,236

(22) Filed: Mar. 21, 2012

(51) Int. Cl. C23C 14/35

(52) U.S. Cl. 204/192.26

(57) ABSTRACT

A deep-UV optical coating preparation method includes the step of putting a high purity metal ingot and a substrate in a sputter chamber and electrically connecting a sputter power supply to the sputter chamber and the step of applying an inertia gas, oxygen and a fluorinated gas to the sputter chamber for causing deposition of a high-refraction fluorine-doped metal oxide film and a low-refraction metal fluoride film to form a deep ultraviolet optical coating having excellent optical and mechanical properties on the substrate.

### BACKGROUND OF THE INVENTION

1. Field of the Invention

The present invention relates to fluoride and fluorine-doped metal oxide film preparation technology and more particularly, to a method of preparing a deep ultraviolet optical coating consisting of a high-refraction fluorine-doped metal oxide film and a low-refraction metal fluoride film by employing sputtering deposition using high purity metal as a target material and inertial gas, oxygen and fluorinated gas as reactive gases.

2. Description of the Related Art

Deep ultraviolet optical coating plays an important role in nanotechnology and lithophotography. Fluoride is an important optical material because it has a wide band gap for allowing ultraviolet light to pass directly, avoiding unwanted absorption. Fluoride may be prepared by vapor deposition. However, a fluoride film made by vapor deposition has the drawbacks of low packing density and poor mechanical properties. When a sputtering technique is employed to prepare a fluoride film, the packing density and mechanical properties can be improved. However, a fluoride film made in this method greatly increases its absorption in deep ultraviolet. Adding fluorine during preparation may improve the optical absorption of the fluorine-contained film. However, this measure is not recommended for the reason of high risk of direct application of fluorine. Further, high purity fluoride is usually used as a target material during sputtering. The quality of the target material determines the quality of the prepared film. If the quality of the target material is not excellent, the quality of the fluorine-doped tin oxide will be relatively lowered.

### SUMMARY OF THE INVENTION

The present invention has been accomplished under the circumstances in view. It is the main object of the present invention to provide a method for the preparation of a deep ultraviolet optical coating that has excellent optical and mechanical properties.

To achieve this and other objects of the present invention, a deep ultraviolet optical coating preparation method comprises the step of putting a high purity metal ingot in a sputter chamber at one side as a target material for sputtering deposition and putting a substrate in the sputter chamber opposite to the high purity metal ingot, the step of electrically connecting a sputter power supply to the sputter chamber, and the step of applying an inertia gas, oxygen and a fluorinated gas to the sputter chamber for causing deposition of a high-refraction fluorine-doped metal oxide film and a low-refraction metal fluoride film to form a deep ultraviolet optical coating on the substrate.

### BRIEF DESCRIPTION OF THE DRAWINGS

FIG. 1 is a schematic drawing illustrating an equipment for the preparation of a deep-ultraviolet optical coating on a substrate.

FIG. 2 is a transmittance curve of deep-ultraviolet optical coatings prepared subject to different ratios of fluorinated gas and oxygen according to the present invention.

FIG. 3 is a transmittance curve illustrating the transmittance of a deep-ultraviolet optical coating at the time it was made and the transmittance of the same deep-ultraviolet optical coating 2 weeks after exposure to the air.

### DETAILED DESCRIPTION OF THE PREFERRED EMBODIMENT

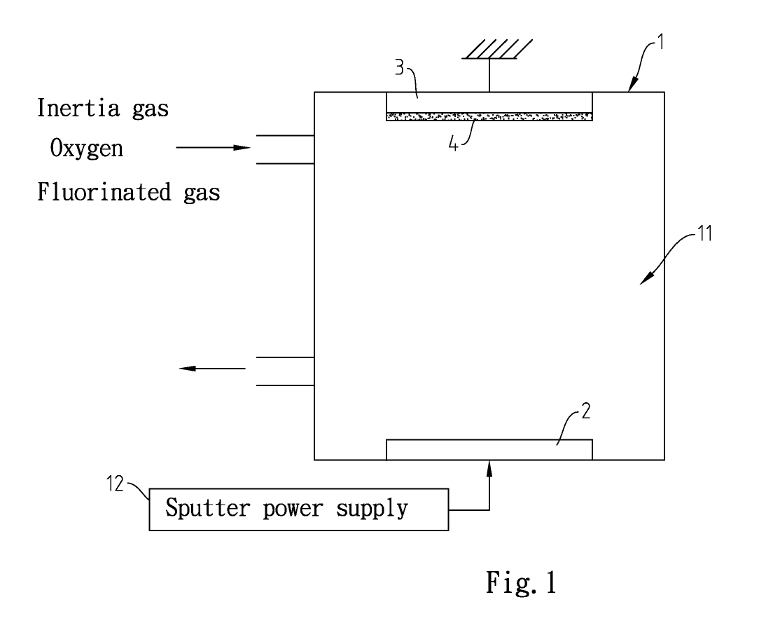

Referring to FIG. 1, a sputtering equipment 1 is shown comprising a sputter chamber 11, a sputter power supply 12 electrically connected to the sputter chamber 11, and a pure metal target 2 and a substrate 3 disposed in the sputter chamber 11 at two opposite sides. When starting sputtering process, an inertia gas, oxygen and a fluorinated gas are supplied to the inside of the sputter chamber 11, causing deposition of a high-refraction fluorine-doped metal oxide film and a low-refraction metal fluoride film on the surface of the substrate 3, and therefore a deep-ultraviolet optical coating 4 is formed on the substrate 3.

When the prepared inertia gas is supplied to the sputter chamber 11 in the sputtering equipment 1, it is excited by the sputter power supply 12 into plasma ions to strike the pure metal target 2 so that de-ionized metal atoms combine with oxygen atoms to form a metal oxide compound, which is then reacted with fluorine ions and excited fluorine atoms, which are de-ionized from the fluorinated gas being applied to the sputter chamber 11, and then deposited on the surface of the substrate 3 to form a high-refraction fluorine-doped metal oxide film.

When the prepared fluorinated gas is supplied to the sputter chamber 11 in the sputtering equipment 1, it is excited by the sputter power supply 12 into fluorine ions and excited fluorine atoms to strike the pure metal target 2 so that de-ionized metal atoms react with active fluorine ions and excited fluorine atoms and then deposited on the surface of the substrate 3, forming a low-refraction metal fluoride film.

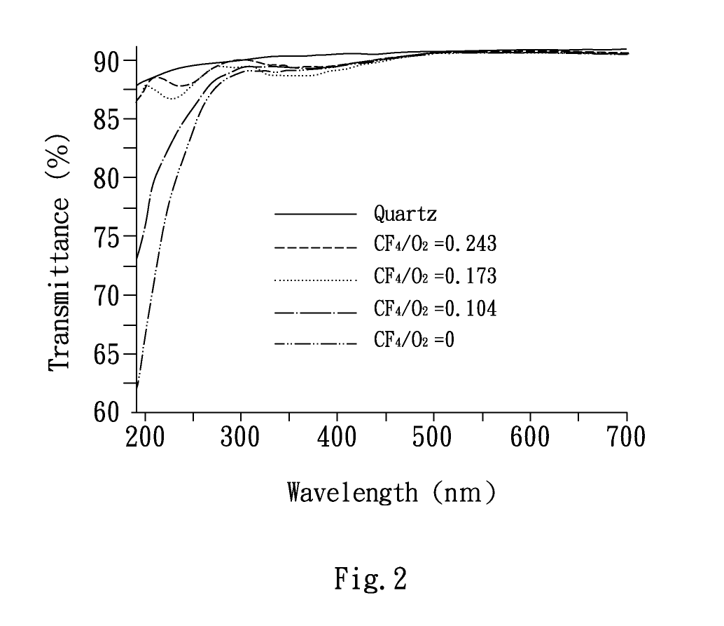

Referring to FIG. 2 and FIG. 1 again, the deep-ultraviolet optical coating 4 can be prepared in one of a series of different alternate forms by changing the ratio between the fluorinated gas and oxygen while maintaining the flow rate of the inertia gas and oxygen. In this embodiment, high purity aluminum (Al) is used for the pure metal target 2; argon (Ar) is used for the inertia gas; tetrafluoromethane (CF₄) is used for the fluorinated gas. When increasing the ratio of tetrafluoromethane (CF₄) and oxygen from 0 to 0.243, the transmittance in the range of deep ultraviolet will be increased over 20%. Thus, the metal fluoride film deposited on the substrate by means of applying the prepared fluorinated gas to the sputter chamber 11 in the sputtering equipment 1 for excitation by the sputter power supply 12 into fluorine ions and excited fluorine atoms greatly enhances the transmittance of the deep ultraviolet coating 4.

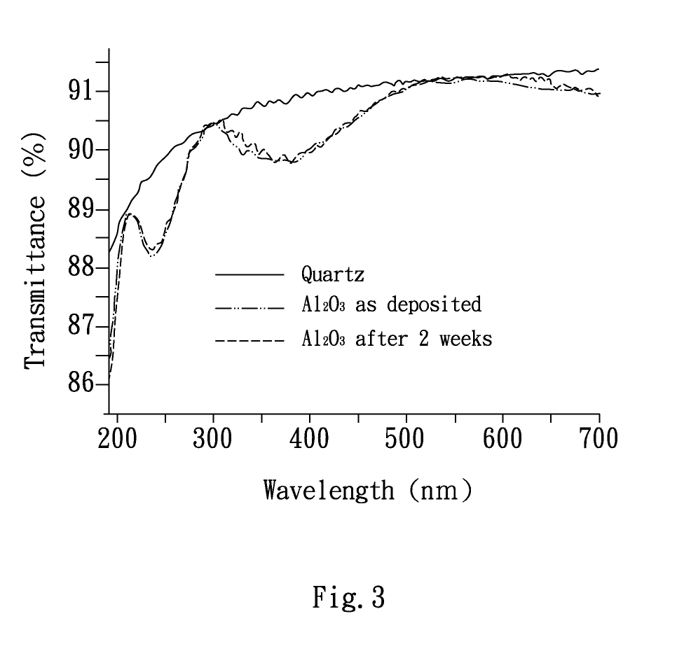

Referring to FIG. 3 and FIG. 1 again, the transmittance of the deep ultraviolet coating 4 measured 2 weeks after prepared and exposure to the air shows no significant change when compared to its transmittance measured at the time when it is made. Due to compact structure, moisture and air are prohibited from permeation into the deep ultraviolet coating 4. This feature proves that the fluorine-doped metal oxide film has excellent mechanical properties.

Further, except tetrafluoromethane (CF₄), hexafluoroethane (CF₆) can also be used as a fluorinated gas to substitute for tetrafluoromethane (CF₄). When tetrafluoromethane (CF₄) is used, adding oxygen can increase the amount of fluorine ions and excited fluorine atoms. Further, the sputter power supply 12 can be magnetron DC (direct current), RF (radio frequency) magnetron, pulsed-DC magnetron or high-power pulsed-DC magnetron type power supply.

In conclusion, the method of the present invention has the advantages and features as follows:

1. The invention uses a pure metal target 2 and apply an inertia gas, oxygen and a fluorinated gas to perform sputtering deposition, forming a deep-UV optical coating 4 consisting of a high-refraction fluorine-doped metal oxide film that enhances the transmittance of the deep-UV optical coating 4 and a low-refraction metal fluoride film that enhances the mechanical properties of the deep-UV optical coating 4.

2. Using a pure metal target 2 and apply an inertia gas, oxygen and a fluorinated gas to perform sputtering deposition effectively reduce deep-UV optical coating preparation cost and avoiding a risk of substantial danger due to direct application of fluorine as used in conventional techniques.

Although particular embodiments of the invention have been described in detail for purposes of illustration, various modifications and enhancements may be made without departing from the spirit and scope of the invention.

What the invention claimed is:

1. A deep-UV optical coating preparation method, comprising the steps of:
(a) putting a high purity metal ingot in a sputter chamber at one side as a target material for sputtering deposition and putting a substrate in said sputter chamber opposite to said high purity metal ingot;
(b) electrically connecting a sputter power supply to said sputter chamber; and
(c) applying an inertia gas, oxygen and a fluorinated gas to said sputter chamber for causing deposition of a high-refraction fluorine-doped metal oxide film and a low-refraction metal fluoride film to form a deep ultraviolet optical coating on said substrate.

2. The deep-UV optical coating preparation method as claimed in claim 1, wherein said inertia gas is applied to said sputter chamber and excited by said sputter power supply into plasma ions to strike said high purity metal ingot so that metal atoms de-ionized from said high purity metal ingot combine with oxygen atoms to form a metal oxide compound, which is then reacted with fluorine ions and excited fluorine atoms, which are de-ionized from said fluorinated gas, and then deposited on said substrate to form said high-refraction fluorine-doped metal oxide film.

3. The deep-UV optical coating preparation method as claimed in claim 1, wherein said fluorinated gas is applied to said sputter chamber and excited by said sputter power supply into fluorine ions and excited fluorine atoms to strike said high purity metal ingot so that metal atoms de-ionized from said pure metal ingot react with active fluorine ions and excited fluorine atoms that are de-ionized from said fluorinated gas, and then deposited on said substrate, forming said low-refraction metal fluoride film.
